(19) United States
(12) Patent Application Publication
(10) Pub. No.: US 2025/0253840 A1
(43) Pub. Date: Aug. 7, 2025

(54) BIDIRECTIONAL POWER SEMICONDUCTOR SWITCH

(71) Applicant: EATON INTELLIGENT POWER LIMITED, Dublin 4 (IE)

(72) Inventor: Kenan ASKAN, Vienna (AT)

(21) Appl. No.: 18/856,232

(22) PCT Filed: Apr. 13, 2023
(86) PCT No.: PCT/EP2023/025175

§ 371 Date: Oct. 11, 2024

(30) Foreign Application Priority Data
Apr. 13, 2022 (GB) 2205520.6

(51) Int. Cl. H03K 17/0812

(52) U.S. Cl. CPC H03K 17/08128; H03K 17/08122

(57) ABSTRACT

Some embodiments relate to a bidirectional power semiconductor switch with a first semiconductor circuit arrangement including a first Si or SiC MOSFET and a second Si or SiC MOSFET and a parallel connected first IGBT and a second IBGT.

A control and driver unit controlling the first and the second silicon or silicon-carbide MOSFETs and the first and the second IGBTs is suggested, that, in a turning on process of the bidirectional power semiconductor switch, the control and driver unit is embodied to switch on at least one of the IGBTs in a first step, and to switch on at least one of the silicon or silicon-carbide MOSFET in a second step, and/or that—in an on-state of the bidirectional power semiconductor switch—the control and driver unit is embodied to keep the previously turned on silicon or silicon-carbide MOSFET and the corresponding IGBT in the on-states.

### CROSS-REFERENCE TO RELATED APPLICATIONS

This application is a national phase filing under 35 C.F.R. § 371 of and claims priority to PCT Patent Application No. PCT/EP2023/025175, filed on Apr. 13, 2023, which claims the priority benefit under 35 U.S.C. § 119 of British Patent Application No. 2205520.6, filed on Apr. 13, 2022, the contents of which are hereby incorporated in their entireties by reference.

### FIELD OF THE DISCLOSURE

The present disclosure relates to a bidirectional power semiconductor switch according to the generic part of claim 1.

### BACKGROUND

The use of solid-state switching devices, particularly, power semiconductor switches in high-power networks is not common, which is due to their different properties. That is why the distribution of solid-state switching devices is limited. A switched-on transistor is part of a conductor path of a power semiconductor switch. In a hybrid circuit breaker, the transistor would only be part of the conductor path during switching on and switching off the solid-state circuit breaker. In solid-state switches, the transistor is always a part of the conductor path. The interposed resistance of a transistor is usually higher than the resistance of a conventional mechanical switch. Owing to the high resistance, the transistor and the switching device are heated, which is why a cooling arrangement is usually used.

Further, different types of transistors have different properties, and not every transistor type can be used in a power semiconductor switch. In the past years, the IGBT, especially the Si-IGBT, was the typical respectively the most used transistor for high-power applications.

All types of transistors cause various types of problems as the main switching part of a power semiconductor switch.

In state-of-the-art applications of solid-state circuit breaker technology such as that disclosed in US2017346478A1, MOSFETs are used due to their unipolar device structure. To be able, use MOSFETs with low break-down voltage, which has lower ON-state resistance, in state of art topologies, TVS (transient voltage suppression) diodes are used due to their lower clamping and leakage current than MOVs (metal oxide varistors). However, TVS diodes are very expensive. In addition, the silicon MOSFETs are not rugged enough against a rapid avalanche breakdown. To avoid damage to the silicon MOSFETs, multiple TVS diodes need to be placed to protect each MOSFET of multiple connected MOSFETs in an appropriate way so that none of the MOSFETs faces the avalanche breakdown. Multiple TVS diodes need to be placed at different points to avoid such possible scenarios.

### SUMMARY OF THE DISCLOSURE

It is an object of the presently disclosed subject matter to overcome the drawbacks of the state of the art by providing a bidirectional power semiconductor switch with a low resistance and low ON-state losses, and which has a long lifetime.

According to the presently disclosed subject matter, the aforementioned object is solved by the features of claim 1.

As a result, the bidirectional power semiconductor switch has a low resistance as the silicon or silicon-carbide MOSFET has a very low resistance. This low resistance becomes much lower when all semiconductors arranged parallel are active. The activeness of the IGBT and the MOSFET lowers the resistance of the semiconductor circuit arrangement. The IGBT connected parallel to the MOSFET reduce the power losses of the bidirectional power semiconductor switch. Therefore, a special cooling device is not required and a classic casing can be used. The bidirectional power semiconductor switch can switch off high currents, as short circuits, very safe, and can also be used to protect the network against short circuits. The bidirectional power semiconductor switch reacts against inside overvoltage, which happens in a switching off process. Switching off processes, also the switching off of high currents, do not limit the lifetime of the solid-state circuit breaker.

As a result, the bidirectional power semiconductor switch has a low resistance in any state. The IGBT can operate in an on-state of the bidirectional power semiconductor switch and decrease on-state power losses, especially at high load currents.

### BRIEF DESCRIPTION OF THE DRAWINGS

The presently disclosed subject matter is described with reference to the drawings. The drawings show only exemplary embodiments of the presently disclosed subject matter.

FIG. 1 shows a first preferred embodiment of a bidirectional power semiconductor switch; and

FIG. 2 shows a second preferred embodiment of a bidirectional power semiconductor switch.

### DETAILED DESCRIPTION

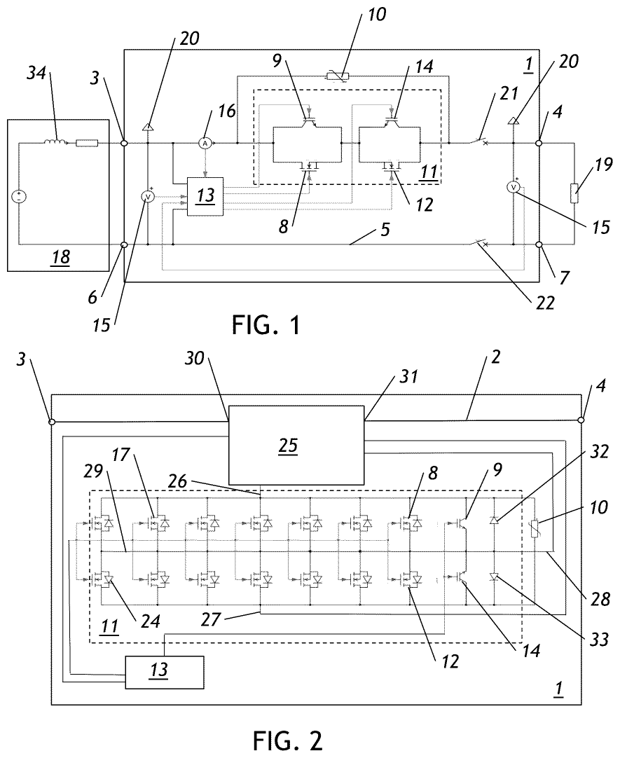

FIGS. 1 and 2 illustrate preferred embodiments of a bidirectional power semiconductor switch 1, comprising:
at least a first outer conductor path 2 from a first outer conductor terminal 3 of the bidirectional power semiconductor switch 1 to a second outer conductor terminal 4 of the bidirectional power semiconductor switch 1,
a first semiconductor circuit arrangement 11 arranged in the first outer conductor path 2, the first semiconductor circuit arrangement 11 comprising:
at least a first silicon or silicon-carbide MOSFET 8 and a second silicon or silicon-carbide MOSFET 12,
at least a first IGBT 9 and a second IGBT 14, the first IGBT 9 is connected parallel to the first silicon or silicon-carbide MOSFET 8 and the second IGBT 14 is connected parallel to the second silicon or silicon-carbide MOSFET 12,
a control and driver unit 13, the control and driver unit 13 controls the first silicon or silicon-carbide MOSFET 8, the second silicon or silicon-carbide MOSFET 12, the first IGBT 9 and the second IGBT 14, and
that—in a turning on process of the bidirectional power semiconductor switch 1—the control and driver unit 13 is embodied to switch on at least one of the first IGBT 9 and the second IGBT 14 in a first step, and to switch on at least one of the first silicon or silicon-carbide MOSFET 8 and the second silicon or silicon-carbide MOSFET 14 in a second step after the first step,
and/or
that—in an on-state of the bidirectional power semiconductor switch 1—the control and driver unit 13 is embodied to keep the first silicon or silicon-carbide MOSFET 8, the second first silicon or silicon-carbide MOSFET 12, the first IGBT 9 and the second IGBT 14 in the on-states.

As a result, the bidirectional power semiconductor switch 1 has a low resistance as the silicon or silicon-carbide MOSFET 8 has a very low resistance. This low resistance becomes much lower when all semiconductors 8, 9 arranged parallel are active. The activeness of the IGBT 9 and the MOSFET 8 lowers the resistance of the semiconductor circuit arrangement 11. The IGBT connected parallel to the MOSFET reduce the power losses of the bidirectional power semiconductor switch 1. Therefore, a special cooling device is not required and a classic casing can be used. The bidirectional power semiconductor switch 1 can switch off high currents, as short circuits, very safe, and can also be used to protect the network against short circuits. The bidirectional power semiconductor switch 1 reacts against inside overvoltage, which happens in a switching off process. Switching off processes, also the switching off of high currents, do not limit the lifetime of the solid-state circuit breaker.

As a result, the bidirectional power semiconductor switch 1 has a low resistance in any state. The IGBT 9 can operate in an on-state of the bidirectional power semiconductor switch 1 and decrease on-state power losses, especially at high load currents.

The present bidirectional power semiconductor switch 1 is preferably a low-voltage solid-state DC device 1. Low voltage is, as usual, in the range up to 1000 V AC and/or 1500 V DC.

The bidirectional power semiconductor switch 1 is a device to operate in an electric grid only with solid-state parts. A bidirectional power semiconductor switch 1 can have and use mechanical switching parts in bypass parts. No mechanical switch, especially no galvanic separation switch 21, 22, is used as disconnecting part for a conductor path 2, 5 of the bidirectional power semiconductor switch 1.

The bidirectional power semiconductor switch 1 can be integrated in another electric device or it can be a separated device with its own casing respectively a separate housing. Preferably the bidirectional power semiconductor switch 1 is part of a low-voltage protection device or embodied as low-voltage protection device. The bidirectional power semiconductor switch 1 can be embodied as device which has only a switching functionality.

The bidirectional power semiconductor switch 1 comprises at least one respectively a first outer conductor path 2 from a first outer conductor terminal 3 of the bidirectional power semiconductor switch 1 to a second outer conductor terminal 4 of the bidirectional power semiconductor switch 1. In case of a three-phase network, the bidirectional power semiconductor switch 1 also comprises a second and a third outer contact path.

Preferably the bidirectional power semiconductor switch 1 also comprises a neutral conductor path 5 from a first neutral conductor terminal 6 of the bidirectional power semiconductor switch 1 to a second neutral conductor terminal 7 of the bidirectional power semiconductor switch 1. FIG. 1 shows a first preferred embodiment comprising the neutral conductor path 5.

In FIG. 1 the illustrated bidirectional power semiconductor switch 1 is connected to an electric source 18 and an electric load 19.

The bidirectional power semiconductor switch 1 preferably comprises a current measuring device 16 arranged in the first outer conductor path 2. According to a preferred embodiment, the bidirectional power semiconductor switch 1 comprises an inductance 34 arranged in the first outer conductor path 2, typically arranged near to the second outer conductor terminal 4. The inductance 34 is limiting the change of rate of current. This inductance 34 either comes due to the internal impedance of the grid and stray inductances or it can be intentionally placed. In case of a solid-state circuit breaker, usually, the internal inductance of the grid and stray inductances are sufficient to limit change of rate of the fault current due to its ultra-high switching speed. This inductance 34 is represented by the inductor is shown in the FIG. 1.

The bidirectional power semiconductor switch 1 comprises a first semiconductor circuit arrangement 11 arranged in the first outer conductor path 2. In a three-phase network a semiconductor circuit arrangement, like the first semiconductor circuit arrangement 11, is arranged in each outer conductor path.

The first semiconductor circuit arrangement 11 comprises at least a first silicon (Si) or silicon-carbide (SiC) MOSFET 8. According to the preferred embodiment, the first semiconductor circuit arrangement 11 comprises at least one additional silicon or silicon-carbide MOSFET 17 connected parallel to the first silicon or silicon-carbide MOSFET 8 and at least one other additional silicon or silicon-carbide MOSFET 24 connected parallel to the second silicon or silicon-carbide MOSFET 12. The parallel connected silicon or silicon-carbide MOSFETs 8, 17 and 12, 24 reduce the resistance in the normal on-state of the bidirectional power semiconductor switch 1, and is a fallback system. The second preferred embodiment according to FIG. 2 has a first and more parallel connected silicon or silicon-carbide MOSFETs 8, 17 and 12, 24.

In addition to the silicon or silicon-carbide MOSFET 8, the first semiconductor circuit arrangement 11 comprises at least a first IGBT 9. The first IGBT 9 is connected parallel to the first silicon or silicon-carbide MOSFET 8 and/or to the parallel connected silicon or silicon-carbide MOSFET 17. Similarly, in addition to the silicon or silicon-carbide MOSFET 12, the first semiconductor circuit arrangement 11 comprises at least a second IGBT 14. The second IGBT 14 is connected parallel to the second silicon or silicon-carbide MOSFET 12 and/or to the parallel connected silicon or silicon-carbide MOSFET 24. Thereby the resistance of the bidirectional power semiconductor switch 1 can be reduced.

Preferably the first semiconductor circuit arrangement 11 comprises a second silicon or silicon-carbide power transistor 12 and a second IGBT 14 arranged in opposite direction to the first silicon or silicon-carbide power transistor 8 and the first IGBT 9. Typically, the second silicon or silicon-carbide power transistor 12 is a silicon or a silicon-carbide MOSFET. A first emitter of the first IGBT 9 is connected to a second emitter of the second IGBT 14. The second IGBT 14 is connected parallel to the second silicon or silicon-carbide power transistor 12 and the arrangement of the second silicon or silicon-carbide power transistor 12 and the second IGBT 14 is circuitry arranged in series and in opposite direction to the arrangement of the first silicon or silicon-carbide power transistor 8 and the first IGBT 9. The first semiconductor circuit arrangement 11 in the first embodiment illustrated in FIG. 1 is embodied in this way.

FIG. 2 shows a second preferred embodiment of a bidirectional power semiconductor switch 1, with additional features to the first semiconductor circuit arrangement 11. In this embodiment, a plurality of silicon or silicon-carbide MOSFET 17 is arranged parallel to a first silicon or silicon-carbide MOSFET 8 and a plurality of silicon or silicon-carbide MOSFET 24 is arranged parallel to a second silicon or silicon-carbide power transistor 12. But the main difference to the embodiment according to FIG. 1 is that the central conductor path 29, which is arranged inside the first semiconductor circuit arrangement 11, is arranged in the connection between the first and the second silicon or silicon-carbide MOSFET 8, 12, between the first and the second IGBT 9, 14 and the other additional silicon or silicon-carbide MOSFETs 17, 24. Further, a blocking diode 32 is connected in parallel with the first IGBT 9 and a second blocking diode 33 is connected in parallel with the second IGBT 14. In this arrangement, the first semiconductor circuit arrangement 11 has three inputs/outputs: the first input/output-connection 26 at the same connection part as shown in FIG. 1, the second input/output-connection 27 at the same connection part as shown in FIG. 1, and a third input/output-connection 28, which is connected with the central conductor path 29. This arrangement enables the functionality of using only two of these three connections as part of the first outer conductor path 2. For these changes, all three input/output-connections 26, 27, 28 are connected with a switching arrangement 25, which is part of the first outer conductor path 2. A first connecting piece 30 of the switching arrangement 25 is connected with the first outer conductor terminal 3 and a second connecting piece 31 of the switching arrangement 25 is connected with the second outer conductor terminal 4. Further, the switching arrangement 25 is connected with the control and driver unit 13. Depending on the requirement, the switching arrangement 25 connects one of the three input/output-connections 26, 27, 28 with the first outer conductor terminal 3 and another one of the three input/output-connections 26, 27, 28 with the second outer conductor terminal 4. Therefore, two of the three input/output-connection 26, 27, 28 are part of the first outer conductor path 2. In this embodiment electric current would not use the completely transistor arrangement of the first semiconductor circuit arrangement 11, but only one side respectively part of this.

In FIG. 2 some preferred parts are not shown, which are for instance the neutral conductor path 5, the voltage measuring device 15, the current measuring device 16, and the galvanic separation relays 21, 22. However, these parts are also preferred parts of the second preferred embodiment of the bidirectional power semiconductor switch 1.

The bidirectional power semiconductor switch 1 comprises a control and driver unit 13 configured to drive respectively control at least the first silicon or silicon-carbide MOSFET 8 and preferably further silicon or silicon-carbide MOSFETs 17, 24, which is shown for example in FIG. 2. The control and driver unit 13 also controls the first IGBT 9. The control and driver unit 13 is connected to each of these parts to communicate with them. Preferably, the control and driver unit 13 comprises a microcontroller.

In preferred embodiments comprising a second or more silicon or silicon-carbide MOSFET 12, 17, 24 and a second IGBT 14, the control and driver unit 13 is connected with each of these transistors 8, 9, 12, 14, 17, 24.

According to the preferred embodiments of the bidirectional power semiconductor switch 1, a first varistor 10, especially embodied as MOV, is connected parallel to the first semiconductor circuit arrangement 11. As a result, the varistor 10 is connected parallel to the transistors 8, 9, 12, 14. The varistor 10 is helpful for switching-off operation against overvoltages.

According to a preferred embodiment, the bidirectional power semiconductor switch 1 comprises at least one voltage measuring device 15. The voltage measuring device 15 is arranged so that the voltage between the first outer conductor path 2 and the neutral conductor path 5 can be measured. Preferably the bidirectional power semiconductor switch 1 comprises two voltage measuring devices 15. One of these two voltage measuring devices 15 is arranged so that the voltage between the first outer conductor terminal 3 and the first semiconductor circuit arrangement 11 can be measured. The second of these two voltage measuring devices 15 is arranged so that the voltage between the first semiconductor circuit arrangement 11 and the second outer conductor terminal 4 can be measured.

In a preferred embodiment, the bidirectional power semiconductor switch 1 comprises a first galvanic separation relay 21 arranged in the first outer conductor path 2 between the first semiconductor circuit arrangement 11 and the second outer conductor terminal 4. Further, the bidirectional power semiconductor switch 1 comprises preferably a second galvanic separation relay 22 arranged in the neutral conductor path 5 between the first semiconductor circuit arrangement 11 and the second neutral conductor terminal 7.

If the bidirectional power semiconductor switch 1 comprises at least one galvanic separation relay 21, 22 and further a voltage measuring device 15, this voltage measuring device 15 is arranged between the galvanic separation relay 21, 22 and the second outer conductor terminal 4.

According to a preferred embodiment, the voltage measuring device 15 or the two voltage measuring devices 15 and the current measuring device 16 are connected with the control and driver unit 13. Further, preferably the voltage measuring device 15 or the two voltage measuring devices 15 comprise connections 20 to deliver the measured voltage levels of other devices, especially a low-voltage protection device, to the voltage measuring device 15 or the two voltage measuring devices 15.

In a turning on process of the bidirectional power semiconductor switch 1, at least one of the first IGBT 9 and the second IGBT 14 and at least one of the first silicon or silicon-carbide MOSFET 8 and the second silicon or silicon-carbide MOSFET 12 are used and activated. In a turn on process, the control and driver unit 13 is embodied to switch on the first IGBT 9 in a first step and to switch on the first silicon or silicon-carbide MOSFET 8 in a second step, whereby the second step is carried out after the first step. Preferably the time between the first step and the second step is in the range of 10-50 microseconds. In case of detection of fault current during the first step, the second step is not conducted. If the bidirectional power semiconductor switch 1 comprises a second IGBT 14 and a second MOSFET 12, the first and the second IGBT 9, 14 are switched on in the first step, and the first and the second MOSFET 8, 12 are switched on in the second step.

Preferably, during the turn on process of the bidirectional power semiconductor switch 1, the control and driver unit 13 is embodied to drive the at least one IGBT 9 with a gate voltage which is slightly above the gate threshold voltage of the at least one IGBT 9, more preferably, 6 to 9 V above the gate threshold voltage of the at least one IGBT 9, so that in case of a fault present at output of the bidirectional power semiconductor switch 1, the desaturation of collector-emitter voltage of the IGBT 9 will occur at low fault currents. In an embodiment in which the first semiconductor circuit arrangement 11 comprises a second silicon or silicon-carbide power transistor 12 and a second IGBT 14 arranged in opposite direction to the first silicon or silicon-carbide power transistor 8 and the first IGBT 9, as illustrated in FIG. 1, during turn on process of the semiconductor circuit arrangement 1, the control and driver unit 13 is embodied to drive each of the first IGBT 9 and the second IGBT 14 with gate voltage which is slightly above the respective gate threshold voltages, more preferably, 6 to 9 V above the respective gate threshold voltages.

In an embodiment, before turning on the first silicon or silicon-carbide MOSFET 8, the gate voltage of the IGBT 9 is increased to a higher value, preferably, by 20 to 25 V, so that trans-conduction of the IGBT 9 is increased and as a result, the IGBT 9 can handle a large current during a short time with a sufficient active semiconductor area. In an embodiment in which the first semiconductor circuit arrangement 11 comprises a second silicon or silicon-carbide MOSFET 12 and a second IGBT 14 arranged in opposite direction to the first silicon or silicon-carbide power transistor 8 and the first IGBT 9, as illustrated in FIG. 1, before turning on the first silicon or silicon-carbide MOSFET 8 and the second silicon or silicon-carbide MOSFET 12, the gate voltage of each of the first IGBT 9 and the second IGBT 14 is increased to a higher value, preferably, by 20 to 25 V.

It is possible that a fault, for example a short circuit, exists at the moment when a switch-on process is carried out. A complete switch-on process under fault conditions can cause various problems for the bidirectional power semiconductor switch 1 itself and also the connected load 19. Even if a further protective device is arranged it is better not to switch-on the bidirectional power semiconductor switch 1. Preferably the bidirectional power semiconductor switch 1 has a desaturation detection function. In an embodiment, short circuit detection is performed by using a ‘DESAT’ function of the first IGBT 9 and second IGBT 14, as a secondary fault current detection mechanism. The current measurement unit 16 is the primary fault current detection mechanism. The secondary fault current measurement can be faster than the primary fault current detection mechanism.

According to a preferred embodiment, the control and driver unit 13 is embodied to detect a desaturation situation of the first IGBT 9 and/or the second IGBT 14, and to turn off the first IGBT 9 and/or the second IGBT 14 if a desaturation of the first IGBT 9 and/or the second 14 is detected. A desaturation of the IGBT 9 and/or the second IGBT 14 can be caused by a fault current, which can be easily detected, due to applied gate voltage slightly higher than gate-threshold voltage, which results in lower transconductance of the IGBTs 9 and 14 and going in desaturation of the voltage at smaller collector current.

In the bidirectional power semiconductor switch 1 the first silicon or silicon-carbide MOSFET 8 and the first IGBT 9 are both used in a normal operation respectively in an on-state of the bidirectional power semiconductor switch 1. The control and driver unit 13 is embodied to keep the first silicon or silicon-carbide MOSFET 8 and the first IGBT 9 in the on-states, when the bidirectional power semiconductor switch 1 is active respectively connected to the input and the output. Even though both MOSFETs and IGBTs are in on-state, the current from input to output flows through the first quadrant and the third quadrant of the MOSFET. The voltage drop on the first and third quadrants is not sufficient to turn on p-n junctions of the IGBT and the blocking diode. This is because of having multiple MOSFETs in parallel to decrease on-state resistance of the bidirectional power semiconductor switch 1 so that the ohmic losses are relatively small. In case of over-currents or fault currents, the voltage drop in the first and third quadrants is higher than the p-n junction voltage which is usually between 0.5 V and 0.7 V per IGBT or blocking diode. As the IGBT will conduct current as well, the losses in MOSFETs will be limited. This lowers the resistance of the bidirectional power semiconductor switch 1.

Additionally, to the switch-on operation, and to the normal operation of the bidirectional power semiconductor switch 1, a turning off process of the bidirectional power semiconductor switch 1 is possible. For this turning off process, the control and driver unit 13 is preferably embodied to increase the gate voltage of the IGBTs from 6-9 V to 20-24 V. After this, the control and driver unit 13 drives MOSFETs to be switched off. After successful current commutation from MOSFETs to IGBTs and diodes, the first IGBT 9 and/or the second IGBT 14 are switched off. By this, then it is guaranteed that all MOSFETs are safely turned off and none of them faces possible avalanche breakdown due to the time difference between turning-off time of multiple parallel-connected MOSFETs. The overvoltage protection device 10 can be either a metal-oxide varistor (MOV) and a transient-voltage-suppression (TVS), and a turn-off snubber network has to be provided to protect the bidirectional power semiconductor switch 1 against over-voltage and decrease fault current to zero by having its voltage higher than the source voltage.

In state-of-the-art applications of solid-state circuit breaker technology such as that disclosed in US2017346478A1, MOSFETs are used due to their unipolar device structure. This is to say that there is no offset voltage (0.5 to 0.7 V) like in IGBTs and p-n silicon diodes. This results in lower ON-state losses of the bidirectional switches. To be able use MOSFETs with low break-down voltage, which has lower on-state resistance, in state of art topologies, TVS (transient voltage suppression) diodes are used due to their lower clamping and leakage current than MOVs (metal oxide varistors). However, TVS diodes are very expensive. In solid-state circuit breaker applications, multiple MOSFETs are usually connected in parallel to decrease the total on-state resistance of a bidirectional switch. Therefore, some of the parallel connected MOSFETs are not able to be placed close to the overvoltage protection device, in this case, a TVS diode. In addition, the silicon MOSFETs are not rugged enough against a rapid avalanche breakdown. On facing an avalanche during turn off, the MOSFETs can immediately get a defect. To avoid this, multiple TVS diodes need to be placed to protect each MOSFET of multiple connected MOSFETs in an appropriate way so that none of the MOSFETs faces the avalanche breakdown. Multiple TVS diodes need to be placed at different points to avoid such possible scenarios. The semiconductor circuit arrangement 1 of the present disclosure solves this problem. A single overvoltage protection device in the form of a varistor 10 is placed in the vicinity of the IGBTs 9, 14. Specifically, the overvoltage protection device 10 is connected between collector terminals of IGBTs 9, 14 so as to minimize stray inductances of interconnection. For example, this can be achieved by placing no other electrical or electronic component and/or any conducting lines between the overvoltage protection device 10 and the IGBTs 9, 14 on the circuit board. The current is turned off at the instant after successful current commutation from MOSFETs 8, 12 to IGBTs 9, 14. Now, MOSFETs 8, 12 have been all successfully turned off and there is practically no current flowing through the stray inductance of the MOSFETs 8, 12. The current flows only through IGBTs 9, 14 and inductances on the current flowing path. As the current is turned off only from one point and the MOSFETs 8, 12 have been already safely turned off, a more reliable and cost-effective bidirectional switch can be realized.

As a result, the bidirectional power semiconductor switch 1 has a low resistance, as the silicon or silicon-carbide MOSFETs 8, 12 have a very low resistance. Therefore, a special cooling device is not needed and a classic casing can be used. The bidirectional power semiconductor switch 1 can switch off short circuits very safe, and can protect the network against short circuits. The bidirectional power semiconductor switch 1 reacts against overvoltage parts happening in a switching off process. Switching off processes, also the switching off of high currents, would not limit the lifetime of the bidirectional power semiconductor switch 1.

In case of a short circuit or in another shutdown the control and driver unit 13 can also begin the switch-off of the bidirectional power semiconductor switch 1. In this case, the control and driver unit 13 is embodied to switch off respectively deactivate the first silicon or silicon-carbide MOSFET 8. If the bidirectional power semiconductor switch 1 further comprises a second silicon or silicon-carbide power transistor 12, the control and driver unit 13 also switches-off the second silicon-carbide MOSFET 12. The control and driver unit 13 further switches off the IGBT 9, 14 in a second step.

While the presently disclosed subject matter has been particularly shown and described with reference to exemplary embodiments thereof, it will be understood by those skilled in the art that various changes in form and details may be made therein without departing from the spirit and scope of the presently disclosed subject matter as defined by the appended claims. The exemplary embodiments should be considered as descriptive only and not for purposes of limitation. Therefore, the scope of the presently disclosed subject matter is not defined by the detailed description but by the appended claims.

Hereinafter are principles for understanding and interpreting the actual disclosure.

Features are usually introduced with an indefinite article “one, a, an”. Unless otherwise stated in the context, therefore, “one, a, an” is not to be understood as a numeral.

The conjunction “or” has to be interpreted as inclusive and not as exclusive, unless the context dictates otherwise. “A or B” also includes “A and B”, where “A” and “B” represent random features.

By means of an ordering number word, for example “first”, “second” or “third”, in particular a feature X or an object Y is distinguished in several embodiments, unless otherwise defined by the disclosure of the presently disclosed subject matter. In particular, a feature X or object Y with an ordering number word in a claim does not mean that an embodiment of the presently disclosed subject matter covered by this claim must have a further feature X or another object Y.

An “essentially” in conjunction with a numerical value includes a tolerance of ±10% around the given numerical value, unless the context dictates otherwise.

For ranges of values, the endpoints are included, unless the context dictates otherwise.

1. A low-voltage protection device comprising a bidirectional power semiconductor switch, wherein the bidirectional power semiconductor switch comprises:
at least a first outer conductor path from a first outer conductor terminal of the bidirectional power semiconductor switch to a second outer conductor terminal of the bidirectional power semiconductor switch,
a first semiconductor circuit arrangement arranged in the first outer conductor path, the first semiconductor circuit arrangement comprising:
at least a first silicon or silicon-carbide MOSFET and a second silicon or silicon-carbide MOSFET,
at least a first IGBT and a second IGBT, the first IGBT is connected parallel to the first silicon or silicon-carbide MOSFET, and the second IGBT is connected parallel to the second silicon or silicon-carbide MOSFET wherein the second IGBT and second MOSFET are arranged in opposite direction to the first IGBT and first MOSFET,
a control and driver unit, the control and driver unit controls the first silicon or silicon-carbide MOSFET, the second silicon or silicon-carbide MOSFET, the first IGBT and the second IGBT, and
wherein, in a turning on process of the bidirectional power semiconductor switch, the control and driver unit is embodied to switch on at least one of the first IGBT and the second IGBT in a first step, wherein during the turning on process of the bidirectional power semiconductor switch, the control and driver unit is embodied to drive the first IGBT and/or the second IGBT with a gate voltage which is slightly above the gate threshold voltage of the first IGBT or the second IGBT respectively.

2. The low-voltage protection device of claim 1 wherein, in the turning on process of the bidirectional power semiconductor switch, the control and driver unit is embodied to detect a desaturation situation of the first IGBT or the second IGBT, and to turn off the first IGBT and second IGBT if a desaturation of the first IGBT or the second IGBT is detected.

3. The low-voltage protection device of claim 1, wherein in a turning off process of the bidirectional power semiconductor switch the control and driver unit is embodied to first switch off at least one of the first silicon or silicon-carbide MOSFET or the second MOSFET, and to switch off the corresponding IGBT in a second step after the first step.

4. The low-voltage protection device of claim 1, wherein the bidirectional power semiconductor switch comprises at least one over-voltage protection device connected parallel to the first semiconductor circuit arrangement.

5. The low-voltage protection device of claim 1, wherein the arrangement of the second silicon or silicon-carbide MOSFET and the second IGBT is arranged in series to the arrangement of the first silicon or silicon-carbide MOSFET and the first IGBT.

6. (canceled).

7. The low-voltage protection device of claim 1, wherein a galvanic separation device connected in series with the bidirectional power semiconductor switch.

8. (canceled).

9. A low-voltage protection device comprising a bidirectional power semiconductor switch according to claim 1, wherein before switching ON the MOSFETs, the gate voltage of the IGBTs is increased to a higher value.

10. A low-voltage protection device comprising a bidirectional power semiconductor switch according to claim 1, short circuit detection is performed by using DESAT function of IGBTs.

11. A low-voltage protection device comprising a bidirectional power semiconductor switch according to claim 1, at least one parallel connected MOSFET that is connected in parallel to the first silicon or silicon-carbide MOSFET.

12. A low-voltage protection device comprising a bidirectional power semiconductor switch according to claim 1, the overvoltage protection device is placed in the vicinity of IGBTs.

13. The low-voltage protection device according to claim 1, wherein the control and driver unit is embodied to drive the first IGBT and/or the second IGBT with a gate voltage which is between 6 V-9 V above the gate threshold voltage of the first IGBT or the second IGBT respectively.

14. The low-voltage protection device of claim 1, wherein in an on-state of the bidirectional power semiconductor switch—the control and driver unit is embodied to keep at least the previously turned on silicon or silicon-carbide MOSFET and the corresponding IGBT in the on-states.

15. The low-voltage protection device according to claim 9, wherein before switching ON the MOSFETs, the gate voltage of each of the IGBTs is increased by between 20 V-25 V.
